(19) United States
(12) Patent Application Publication
(10) Pub. No.: US 2026/0123492 A1
(43) Pub. Date: Apr. 30, 2026

(54) SEMICONDUCTOR PACKAGE INCLUDING CONNECTORS AND METHOD FOR MANUFACTURING THE SAME

(71) Applicant: SAMSUNG ELECTRONICS CO., LTD., SUWON-SI (KR)

(72) Inventor: Do Hyuk YOO, Suwon-si (KR)

(21) Appl. No.: 19/229,497

(22) Filed: Jun. 5, 2025

(30) Foreign Application Priority Data
Oct. 29, 2024 (KR) 10-2024-0149367

(51) Int. Cl. H01L 23/00; H01L 21/48; H01L 23/498

(52) U.S. Cl. CPC H10W 70/69; H10W 90/701; H10W 99/00; H10W 72/01257; H10W 72/072; H10W 72/07202; H10W 72/07252; H10W 72/07253; H10W 72/221; H10W 72/234; H10W 72/285; H10W 74/15; H10W 90/724; H10W 90/734

(57) ABSTRACT

A semiconductor package and a method for manufacturing a semiconductor package includes a base substrate including a first surface and a second surface, a first contact pad disposed on the first surface of the base substrate, a first solder resist layer disposed on the first surface of the base substrate, a second solder resist layer covering a portion of an upper surface of the first solder resist layer, and a first connector disposed in the first opening area and the second opening area. The first solder resist layer covers a side surface and a portion of an upper surface of the first contact pad, and defines a first opening area on the first contact pad. The first connector is in contact with the first contact pad. A first width of the first opening area is smaller than a second width of the second opening area.

### CROSS-REFERENCE TO RELATED APPLICATION

This application claims priority under 35 U.S.C. § 119 to Korean Patent Application No. 10-2024-0149367, filed on Oct. 29, 2024, in the Korean Intellectual Property Office, the entire contents of which are herein incorporated by reference.

### TECHNICAL FIELD

The present disclosure relates to a semiconductor device and, more specifically to the semiconductor device including connectors, an electronic system including the same, and a method for manufacturing the semiconductor device.

### DISCUSSION OF THE RELATED ART

In a semiconductor device, as a chip size decreases and the number of input/output terminals increases due to the miniaturization of process technology and the diversification of functions, an electrode pad pitch is gradually miniaturized.

### SUMMARY

According to an aspect of the present disclosure, there is provided a semiconductor package including a base substrate including a first surface and a second surface, a first contact pad disposed on the first surface of the base substrate, a first solder resist layer disposed on the first surface of the base substrate, a second solder resist layer covering a portion of an upper surface of the first solder resist layer, and a first connector disposed in the first opening area and the second opening area. The first surface and the second surface of the base substrate are opposite to each other along a first direction. The first solder resist layer covers a side surface and a portion of an upper surface of the first contact pad, and defines a first opening area on the first contact pad. The first connector is in contact with the first contact pad. A second direction is parallel to the first surface, and a first width of the first opening area measured along the second direction is smaller than a second width of the second opening area measured along the second direction.

According to another aspect of the present disclosure, there is provided a semiconductor package including a base substrate including a first surface and a second surface, a first contact pad disposed on the first surface, a first solder resist layer disposed on the first surface and covering a side surface and a portion of an upper surface of the first contact pad, a second solder resist layer covering a portion of an upper surface of the first solder resist layer, a first connector disposed in the first opening area and the second opening area, a semiconductor chip disposed on and in contact with the first connector and electrically connected to the first contact pad, and an underfill film disposed between the semiconductor chip and the second solder resist layer and surrounding the first connector. The first surface and the second surface of the base substrate are opposite to each other along a first direction. The first solder resist layer defines a first opening area on the first contact pad. The second solder resist layer defines defining a second opening area on the first contact pad and the first solder resist layer. The first connector is in contact with the first contact pad. A second direction is parallel to the first surface, and a first width of the first opening area measured along the second direction is smaller than a second width of the second opening area measured along the second direction. The first connector protrudes in the first direction beyond the second solder resist layer

According to an aspect of the present disclosure, there is provided a method for manufacturing a semiconductor package including providing a base substrate including a first surface and a second surface, disposing a contact pad on the first surface, disposing a first solder resist layer on the first surface and covering a side surface and a portion of an upper surface of the contact pad, disposing a second solder resist layer covering a portion of an upper surface of the first solder resist layer, and mounting a semiconductor chip on the first surface, such that it is electrically connected to the contact pad. The first surface and the second surface of the base substrate are opposite to each other along a first direction. The first solder resist layer defines a first opening area on the contact pad. The second solder resist layer defines a second opening area on the contact pad and the first solder resist layer. The semiconductor chip includes a chip connector disposed in the first opening area and the second opening area, and in contact with the contact pad. A second direction is parallel to the first surface, and a first width of the first opening area measured along the second direction is smaller than a second width of the second opening area measured along the second direction.

### BRIEF DESCRIPTION OF DRAWINGS

The above and other aspects and features of the present disclosure will become more apparent by describing in detail embodiments thereof with reference to the attached drawings, in which:

FIG. 1 is a schematic layout diagram for illustrating a semiconductor package according to embodiments of the present disclosure.

FIG. 2 is a schematic cross-sectional view taken along a line A-A of FIG. 1.

FIGS. 3, 4, 5, and 6 are enlarged cross-sectional views illustrating an area of R1 of FIG. 2.

FIGS. 7 and 8 are cross-sectional views illustrating a semiconductor package according to embodiments of the present disclosure.

FIGS. 9 and 10 are cross-sectional views illustrating a semiconductor package according to embodiments of the present disclosure.

FIGS. 11 and 12 are diagrams for illustrating a semiconductor package according to embodiments of the present disclosure.

FIG. 13 is a schematic cross-sectional view for illustrating a semiconductor package according to embodiments of the present disclosure.

FIGS. 14, 15, 16, 17, 18, 19, 20, 21, and 22 are diagrams illustrating intermediate structures corresponding to intermediate steps of a method for manufacturing a semiconductor package according to embodiments of the present disclosure.

### DETAILED DESCRIPTIONS

Hereinafter, embodiments of the present disclosure will be described in detail with reference to the accompanying drawings. The same reference numerals may be used to represent like elements throughout the specification and the figures and to the extent that an element has not been described in detail, it may be assumed that the element is at least similar to corresponding elements that have been described in previous figures.

Although terms such as first, second, upper, and lower are used herein to describe various elements or components, these element or components are not necessarily limited by the terms. Rather, the terms are merely used herein to distinguish one element or component from another element or component. Therefore, a first element or component as mentioned below may also be a second element or component within the technical spirit of the present disclosure. Further, a lower element or component as mentioned below may also be an upper element or component within the technical spirit of the present disclosure.

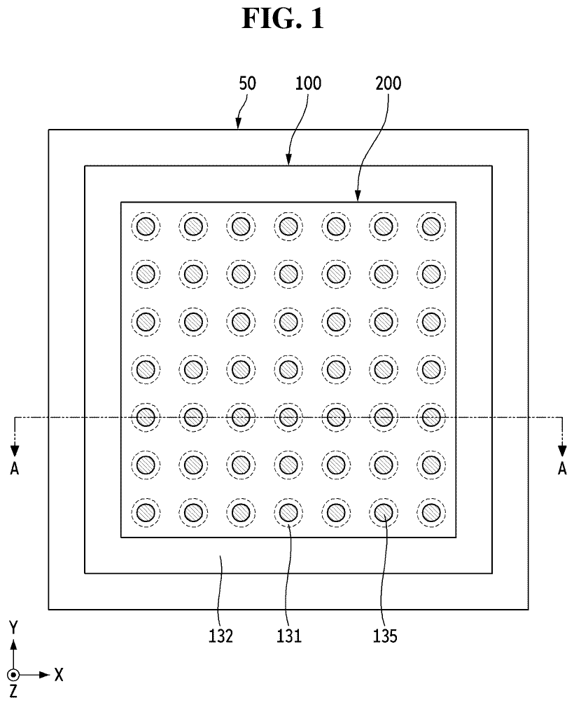

Hereinafter, a semiconductor package according to embodiments of the present disclosure will be described with reference to FIGS. 1 to 13.

According to embodiments of the present disclosure, solder resist layers may define areas where the chip connectors can attach to the contact pads. The solder resist layers may create opening areas. The opening areas may ensure that the chip connectors fit correctly and maintain electrical integrity between a semiconductor chip, chip substrate, and circuit substrate. Chip connectors, such as solder balls or bumps, may be disposed within the opening areas and may help connect the contact pads and maintain proper electrical connection between the different layers of the package.

According to embodiments of the present disclosure, a multi-layered solder resist layers may be sequentially stacked and create a step shape structure. The step shaped solder resist layers may prevent misalignment of chip connectors. For example, when multiple layers of solder resist layers are stacked in the step shape, with a slight vertical offset between layers, the solder resist layers may create a boundary. The solder resist layers may help ensure that the solder balls or connection pads are aligned correctly during an assembly process. The step shaped solder resist layers may push or force the components to settle into place, reducing the risk of electrical shorts or poor connections.

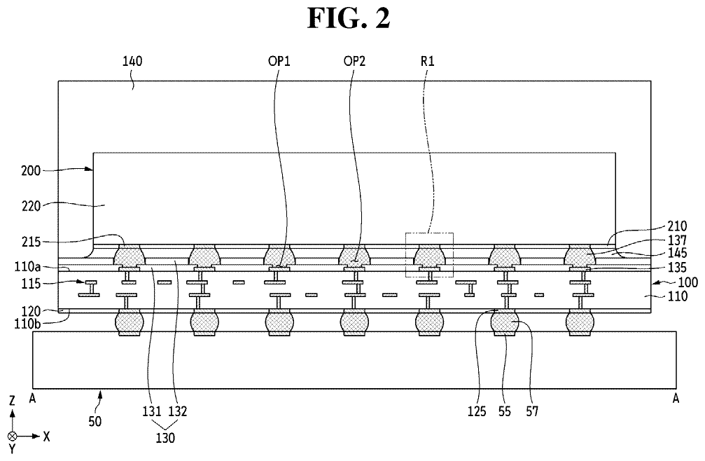

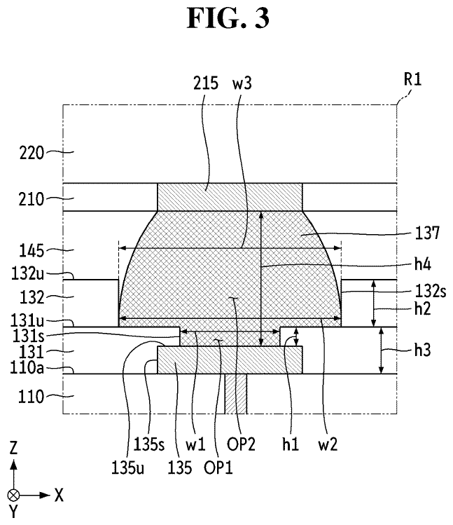

FIG. 1 is a schematic layout diagram for illustrating a semiconductor package according to embodiments of the present disclosure. FIG. 2 is a schematic cross-sectional view taken along a line A-A of FIG. 1. FIGS. 3 to 6 are various enlarged views for illustrating an area R1 of FIG. 2.

The semiconductor package according to embodiments of the present disclosure may be a package included in a PIP (package-in-package) or a POP (package-on-package).

Referring to FIGS. 1 to 6, the semiconductor package according to embodiments of the present disclosure may include a circuit substrate 50, a chip substrate 100, and a semiconductor chip 200.

The chip substrate 100 and the semiconductor chip 200 may be disposed on the circuit substrate 50 in a third direction Z. The semiconductor chip 200 may be disposed on the chip substrate 100 in the third direction Z. For example, the chip substrate 100 may be disposed between the circuit substrate 50 and the semiconductor chip 200. The chip substrate 100 may electrically connect the circuit substrate 50 and the semiconductor chip 200 to each other. As used herein, a first direction X and a second direction Y may intersect the third direction Z, and the first direction X and the second direction Y may intersect each other. For example, the first direction X, the second direction Y, and the third direction Z may be substantially perpendicular to each other.

The circuit substrate 50 may be a substrate for a package. For example, the circuit substrate 50 may be a printed circuit board (PCB). The circuit substrate 50 may be mounted on a main substrate or the like of an electronic device. The circuit substrate 50 may be mounted on a main substrate or the like of the electronic device through a contactor. The contactor may have, for example, a solder ball shape.

The circuit substrate 50 may include a package contact pad 55. The package contact pad 55 may be disposed on an upper surface of the circuit substrate 50. In this regard, the upper surface may refer to a surface adjacent to the chip substrate 100. The package contact pad 55 may include a conductive material, for example, a metal.

The chip substrate 100 may include a base substrate 110, a conductive pattern 115, a lower passivation film 120, an upper passivation film 130, a second contact pad 125, and a first contact pad 135.

The chip substrate 100 may be electrically connected to the circuit substrate 50 through a package connector 57. The package connector 57 may be disposed between the chip substrate 100 and the circuit substrate 50. For example, the package connector 57 may be disposed between the package contact pad 55 and the second contact pad 125. The package connector 57 may be in contact with the chip substrate 100 and the circuit substrate 50. The package connector 57 may be in contact with the package contact pad 55 of the circuit substrate 50 and the second contact pad 125 of the chip substrate 100. The package connector 57 may have, for example, a solder ball shape. The package connector 57 may include a metal, for example, tin (Sn), indium (In), bismuth (Bi), antimony (Sb), copper (Cu), silver (Ag), zinc (Zn), lead (Pb), or a combination thereof.

The base substrate 110 may include a first surface 110a and a second surface 110b. The first surface 110a and the second surface 110b may extend along the first and second directions X and Y. For example, the first surface 110a and the second surface 110b of the base substrate 110 may intersect the third direction Z in a perpendicular manner. The first surface 110a and the second surface 110b of the base substrate 110 may be disposed opposite to each other along the third direction Z. For example, the first surface 110a may refer to a top surface of the base substrate 110 and the second surface 110b may refer to a bottom surface of the base substrate 110. The second surface 110b of the base substrate 110 may be disposed adjacent to the circuit substrate 50. The first surface 110a of the base substrate 110 may be disposed adjacent to the semiconductor chip 200.

The base substrate 110 is illustrated as a single layer. However, embodiments of the present disclosure are not necessarily limited thereto. The base substrate 110 may be comprised of, for example, a plurality of layers. The base substrate 110 may include an insulating material.

The conductive pattern 115 may be disposed in the base substrate 110. The conductive pattern 115 may be in contact with the first contact pad 135 and the second contact pad 125. The conductive pattern 115 may electrically connect the first contact pad 135 and the second contact pad 125 to each other. The number or arrangement of the conductive patterns 115 as illustrated in FIG. 2 are merely examples, and the technical idea of the present disclosure is not necessarily limited thereto. The conductive pattern 115 may include a conductive material, for example, a metal.

The lower passivation film 120 may be disposed under the chip substrate 100. The lower passivation film 120 may be disposed on the second surface 110b of the base substrate 110. The lower passivation film 120 may cover the second surface 110b of the base substrate 110. A bottom surface of the lower passivation film 120 may be disposed adjacent to the circuit substrate 50. The lower passivation film 120 may include an insulating material, for example, photo-imageable dielectric (PID).

The second contact pad 125 may be disposed in the lower passivation film 120. The second contact pad 125 may be surrounded with the lower passivation film 120. For example, the lower passivation film 120 may cover side surfaces of the second contact pad 125. The second contact pad 125 may be disposed at the same level as that of the lower passivation film 120. In this regard, “disposed at the same level” may mean disposed at the same vertical level. In embodiments of the present disclosure, an upper surface and a bottom surface of the second contact pad 125 may be disposed at the same vertical levels as those of an upper surface and a bottom surface of the lower passivation film 120, respectively.

The second contact pad 125 might not be covered with the lower passivation film 120 so as to be exposed along the third direction Z. For example, the second contact pad 125 might not surround the top surface and the bottom surface of the lower passivation film 120. For example, the second contact pad 125 may be in contact with the base substrate 110, the conductive pattern 115, and the package connector 57. For example, an upper surface of the second contact pad 125 may contact the base substrate 110 and the conductive pattern 115 and a bottom surface of the second contact pad 125 may contact the package connector 57.

The second contact pad 125 may be electrically connected to the conductive pattern 115. The second contact pad 125 may be electrically connected to the package connector 57. For example, the conductive pattern 115 may be electrically connected to the package connector 57 and the circuit substrate 50 through the second contact pad 125. The second contact pad 125 may include a conductive material, for example, a metal.

The first contact pad 135 may be disposed on the first surface 110a of the base substrate 110. A plurality of first contact pads 135 may be arranged side by side along the first direction X and the second direction Y in a matrix form while being disposed on the first surface 110a of the base substrate 110. The first contact pad 135 may be spaced apart from another first contact pad 135 along the first direction X.

The first contact pad 135 may be electrically connected to the conductive pattern 115. The first contact pad 135 may be electrically connected to the circuit substrate 50 through the conductive pattern 115, the second contact pad 125, the package connector 57, and the package contact pad 55. The first contact pad 135 may include a conductive material, for example, a metal. For example, the conductive pattern 115, the second contact pad 125, the package connector 57, and the package contact pad 55 may be disposed between the first contact pad 135 and the circuit substrate 50.

The upper passivation film 130 may be disposed on the chip substrate 100. The upper passivation film 130 may be disposed on the first surface 110a of the base substrate 110. The upper passivation film 130 may be disposed on a portion of the first contact pad 135. The upper passivation film 130 may cover a portion of each of the base substrate 110 and the first contact pad 135. A bottom surface of the upper passivation film 130 may be disposed adjacent to the first surface 110a of the base substrate 110. In embodiments of the present disclosure, as illustrated in FIG. 3, the upper passivation film 130 may cover the first surface 110a of the base substrate 110. The upper passivation film 130 may include an insulating material, for example, photo-imageable dielectric (PID).

The upper passivation film 130 may include a first solder resist layer 131 and a second solder resist layer 132. The first solder resist layer 131 may be disposed on the first surface 110a of the base substrate 110. The second solder resist layer 132 may be disposed on the first solder resist layer 131. For example, the first solder resist layer 131 may be disposed between the base substrate 110 and the second solder resist layer 132. For example, the second solder resist layer 132 might not contact the base substrate 110.

The first solder resist layer 131 may be disposed on the first surface 110a of the base substrate 110. A portion of the first solder resist layer 131 may be disposed on the first contact pad 135. The first solder resist layer 131 may cover a side surface 135s and a portion of an upper surface 135u of the first contact pad 135 and the first surface 110a of the base substrate 110.

For example, in a plan view of FIG. 1, the first solder resist layer 131 might not cover a portion of the upper surface 135u of the first contact pad 135 so as to be exposed along the third direction Z. In FIG. 1, each of the first solder resist layer 131 and the first contact pad 135 is shown in a circular shape in a plan view. However, embodiments of the present disclosure are not necessarily limited thereto, and each of the first solder resist layer 131 and the first contact pad 135 may have a rectangular or square shape in the plan view. As used herein, “plan view” may mean the plan view of FIG. 1.

The first solder resist layer 131 may define a first opening area OP1 above the upper surface 135u of the first contact pad 135. The first opening area OP1 may refer to an area defined by the side surface 131s of the first solder resist layer 131 and the upper surface 135u of the first contact pad 135. In this regard, the side surface 131s of the first solder resist layer 131 may refer to a surface of the first solder resist layer 131 contacting a chip connector 137 along the first direction X and a surface of the first solder resist layer 131 contacting the side surface 135s of the first contact pad 135 in the first direction X.

A width w1 of the first opening area OP1, measured along the first direction X may be smaller than a width of the first contact pad 135, measured along the first direction X. The width w1 of the first opening area OP1 may mean a distance between both opposing side surfaces 131s of the first solder resist layer 131. The width of the first contact pad may mean a distance between both opposing side surfaces 135s of the first contact pad 135.

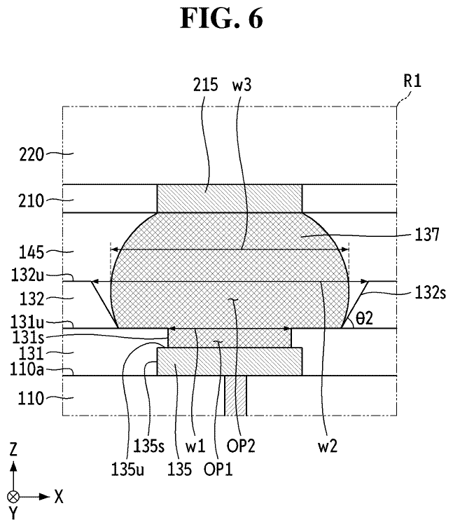

In embodiments of the present disclosure as illustrated in FIGS. 3 and 6, the first opening area OP1 may have a cylindrical shape defined by the side surface 131s of the first solder resist layer 131 and the upper surface 135u of the first contact pad 135.

For example, in embodiments of the present disclosure, the side surface 131s of the first solder resist layer 131 may intersect the first direction X in a perpendicular manner. For example, in cross-sectional views of FIGS. 3 and 6, the side surface 131s of the first solder resist layer 131 may form a 90 degrees angle with respect to the first surface 110a of the base substrate 110 and the upper surface 135u of the first contact pad 135. The chip connector 137 may be disposed in the first opening area OP1. For example, the chip connector 137 may be in contact with the upper surface 135u of the first contact pad 135 and the side surface 131s of the first solder resist layer 131 while filling the first opening area OP1.

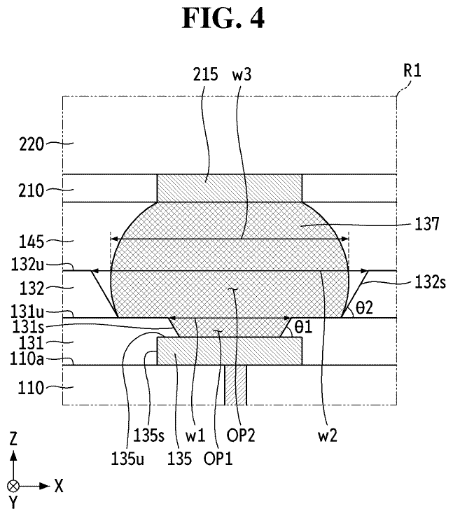

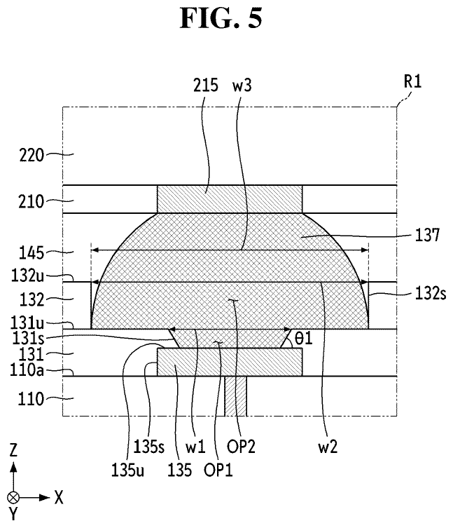

In embodiments of the present disclosure illustrated in FIGS. 4 and 5, the first opening area OP1 may have a shape of a truncated cone defined by the side surface 131s of the first solder resist layer 131 and the upper surface 135u of the first contact pad 135.

For example, in the cross-sectional views of FIGS. 4 and 5, the side surface 131s of the first solder resist layer 131 may form an angle θ1 with respect to the upper surface 135u of the first contact pad 135. The angle θ1 may be an acute angle smaller than 90 degrees. For example, the width w1—of the first opening area OP1, measured along the first direction X, may decrease as the first opening area OP1 extends toward the upper surface 135u of the first contact pad 135. The width w1 of the first opening area OP1 may be greater as it extends toward the upper surface 131u of the first solder resist layer 131.

In embodiments of the present disclosure, the chip connector 137 may be in contact with the upper surface 135u of the first contact pad 135 in the first opening area OP1. When the side surface 131s of the first solder resist layer 131 forms an acute angle of θ1 smaller than an angle of 90 degrees with respect to the upper surface 135u of the first contact pad 135, it may be easier for the chip connector 137 to contact the upper surface 135u of the first contact pad 135 through the first opening area OP1. Accordingly, a semiconductor package having a reduced size and improved performance may be provided.

The second solder resist layer 132 may be disposed on the first solder resist layer 131. For example, the first solder resist layer 131 may be disposed between the second solder resist layer 132 and the base substrate 110. The second solder resist layer 132 may cover a portion of the upper surface 131u of the first solder resist layer 131. The second solder resist layer 132 may overlap the first solder resist layer 131 along the third direction Z. As illustrated, the entirety of the second solder resist layer 132 may overlap the first solder resist layer 131 along the third direction Z. However, embodiments of the present disclosure are not necessarily limited thereto.

For example, in the plan view as illustrated in FIG. 1, the second solder resist layer 132 might not cover a portion of the upper surface 135u of the first contact pad 135 and a portion of the upper surface 131u of the first solder resist layer 131 so as to be exposed along the third direction Z. A portion of each of the first solder resist layer 131 and the first contact pad 135 not covered with the second solder resist layer 132 so as to be exposed is shown in a circular shape. However, embodiments of the present disclosure are not necessarily limited thereto. In addition, in the plan view, the second solder resist layer 132 may include a portion overlapping the semiconductor chip 200 along the third direction Z and a portion not overlapping the semiconductor chip 200 along the third direction Z.

In embodiments of the present disclosure, a vertical distance h1 from the upper surface 135u of the first contact pad 135 to the upper surface 131u of the first solder resist layer 131 may be smaller than a vertical distance h2 from the upper surface 131u of the first solder resist layer 131 to the upper surface 132u of the second solder resist layer 132. The vertical distance h2 from the upper surface 131u of the first solder resist layer 131 to the upper surface 132u of the second solder resist layer 132 may be twice or greater than the vertical distance h1 from the upper surface 135u of the first contact pad 135 to the upper surface 131u of the first solder resist layer 131. For example, the vertical distance h2 from the upper surface 131u of the first solder resist layer 131 to the upper surface 132u of the second solder resist layer 132 may be about 15 μm, and the vertical distance h1 from the upper surface 135u of the first contact pad 135 to the upper surface 131u of the first solder resist layer 131 may be about 5 μm.

Due to the miniaturization of the process technology and the diversification of functions of the semiconductor device, the chip size decreases and the number of input/output terminals increases, and thus the electrode pad pitch is gradually miniaturized. Accordingly, in the process of mounting the chip on the pad of the substrate, the bump of the chip is not properly attached to the pad of the substrate due to misalignment or the like, and thus the performance of the semiconductor package is deteriorated.

In the semiconductor package provided in embodiments of the present disclosure, the first solder resist layer 131 and the second solder resist layer 132 having a step shape may be sequentially stacked on the first contact pad 135 of the chip substrate 100, and a thickness (e.g., h1 of FIG. 3) of the first solder resist layer 131 reduced allows the chip connector 137 to be appropriately attached to the first contact pad 135, thereby preventing the performance of the semiconductor package from being deteriorated. In addition, since the thickness of the first solder resist layer 131 is reduced, the width of the first contact pad 135 to be secured in order to allow the chip connector 137 to be properly attached to the first contact pad 135 may be reduced. Accordingly, a semiconductor package having a reduced size and increased performance may be provided.

In addition, in the semiconductor package provided in embodiments of the present disclosure, the vertical distance h2 from the upper surface 131u of the first solder resist layer 131 to the upper surface 132u of the second solder resist layer 132 may be greater by at least two times than the vertical distance h1 from the upper surface 135u of the first contact pad 135 to the upper surface 131u of the first solder resist layer 131. Accordingly, the side surface 132s of the second solder resist layer 132 may prevent a short circuit between the chip connectors 137, thereby providing a semiconductor package with increased performance.

The second solder resist layer 132 may define a second opening area OP2 above the upper surface 131u of the first solder resist layer 131 and the upper surface 135u of the first contact pad 135. The second opening area OP2 may refer to an area defined by the side surface 132s of the second solder resist layer 132 and the upper surface 131u of the first solder resist layer 131. For example, the second opening area OP2 may overlap the first opening area OP1 along the third direction Z. For example, the second opening area OP2 may be disposed above the first opening area OP1. The second opening area OP2 may be in contact with the first opening area OP1.

A width w2 of the second opening area OP2 measured along the first direction X may be greater than the width of the first contact pad 135 measured along the first direction X. A width w2 of the second opening area OP2 measured along the first direction X may be greater than the width w1 of the first opening area OP1 measured along the first direction X. For example, the width of the first contact pad 135 may be greater than the width w1 of the first opening area OP1, and the width w2 of the second opening area OP2 may be greater than the width of the first contact pad 135. The width w2 of the second opening area OP2 may mean a distance measured along the first direction X between both opposing side surfaces 132s of the second solder resist layer 132.

In the semiconductor package according to embodiments of the present disclosure, the width w2 of the second opening area OP2 may be greater than the width w1 of the first opening area OP1, so that the chip connector 137 may be disposed on the upper surface 131u of the first solder resist layer 131. For example, the chip connector 137 may be disposed in the first opening area OP1 and the second opening area OP2, thereby preventing a short circuit from occurring between adjacent chip connectors 137. Accordingly, a semiconductor package having increased performance may be provided.

In embodiments of the present disclosure illustrated in FIGS. 3 and 5, the second opening area OP2 may have a cylindrical shape surrounded with the side surface 132 s of the second solder resist layer 132, the upper surface 131u of the first solder resist layer 131, and the upper surface 135u of the first contact pad 135.

In the cross-sectional view of FIG. 3, each of the first opening area OP1 and the second opening area OP2 may have a shape in which a rectangle is disposed in each of horizontal and vertical portions of the letter ‘T’. In the cross-sectional view of FIG. 5, each of the first opening area OP1 and the second opening area OP2 may have a shape in which a trapezoid is disposed at a vertical portion of the letter ‘T’ and a rectangle is disposed at a horizontal portion of the letter ‘T’.

For example, in embodiments of the present disclosure, the side surface 132s of the second solder resist layer 132 may intersect the first direction X in a perpendicular manner. For example, the side surface 132s of the second solder resist layer 132 may form an 90 degrees angle with respect to the upper surface 131s of the first solder resist layer 131 from the cross-sectional view of FIGS. 3 and 5. The chip connector 137 may be disposed in the second opening area OP2. For example, the chip connector 137 may contact the side surface 132s of the second solder resist layer 132, but this is merely an example. Unlike the illustrated case, the chip connector 137 may be disposed in the second opening area OP2 but might not be in contact with the side surface 132 s of the second solder resist layer 132.

In embodiments of the present disclosure illustrated in FIGS. 4 and 6, the second opening area OP2 may have a truncated cone shape defined by the side surface 132 s of the second solder resist layer 132 and the upper surface 131u of the first solder resist layer 131.

In the cross-sectional view of FIG. 4, each of the first opening area OP1 and the second opening area OP2 may have a shape in which a trapezoid is disposed in each of horizontal and vertical portions of the letter ‘T’. In the cross-sectional view of FIG. 6, each of the first opening area OP1 and the second opening area OP2 may have a shape in which a rectangular shape is disposed in a vertical portion of the letter ‘T’ and a trapezoidal shape is disposed in a horizontal portion of the letter ‘T’.

For example, in the cross-sectional views of FIGS. 4 and 6, the side surface 132s of the second solder resist layer 132 may form an angle θ2 with respect to the upper surface 131u of the first solder resist layer 131. The angle θ2 may be an acute angle smaller than 90 degrees. For example, the width w2 in the first direction X of the second opening area OP2 may decrease as the second opening area OP2 extends toward the upper surface 131u of the first solder resist layer 131. For example, the width w2 of the second opening area OP2 may increase as the second opening area OP2 extends toward the chip passivation film 210.

In embodiments of the present disclosure, the chip connector 137 may be disposed in the second opening area OP2. When the side surface 132s of the second solder resist layer 132 forms an acute angle θ2 with respect to the upper surface 131u of the first solder resist layer 131, rather than a case when the side surface 132s of the second solder resist layer 132 forms 90 degrees with respect to the upper surface 131u of the first solder resist layer 131, the chip connector 137 may be stably disposed in the second opening area OP2. Accordingly, a semiconductor package having a reduced size and increased performance may be provided.

In FIG. 4, the angle θ1 and the angle θ2 may be different from each other. This may be a difference occurring during a process of forming each of the first solder resist layer 131 and the second solder resist layer 132, during a process for manufacturing the semiconductor package. For example, the angle θ1 may be greater than the angle θ2. This may be because the vertical distance h1 from the upper surface 135u of the first contact pad 135 to the upper surface 131u of the first solder resist layer 131 is smaller than the vertical distance h2 from the upper surface 131u of the first solder resist layer 131 to the upper surface 132u of the second solder resist layer 132.

The chip connector 137 may be disposed on the chip substrate 100. The chip connector 137 may be disposed between the semiconductor chip 200 and the chip substrate 100. The chip connector 137 may be disposed in the first opening area OP1 and the second opening area OP2. The chip connector 137 may be disposed on the first contact pad 135, the first solder resist layer 131, and the second solder resist layer 132. For example, the first contact pad 135 may be disposed between the chip connector 137 and the base substrate 110. In addition, for example, the first solder resist layer 131 may be interposed between the second solder resist layer 132 and the chip connector 137 and the base substrate 110.

The chip connector 137 may be in contact with the upper surface 135u of the first contact pad 135, the side surface 131s of the first solder resist layer 131, the upper surface 131u of the first solder resist layer 131, and the chip contact pad 215. In embodiments of the present disclosure, the chip connector 137 may further contact the side surface 132s of the second solder resist layer 132.

The chip connector 137 may be electrically connected to the first contact pad 135 and the chip contact pad 215. The chip connector 137 may be electrically connected to the conductive pattern 115, the package connector 57, and the circuit substrate 50 through the first contact pad 135. The chip contact pad 215 may be electrically connected to the conductive pattern 115, the package connector 57, and the circuit substrate 50 through the chip connector 137.

The chip connector 137 may have, for example, a solder ball shape. The chip connector 137 may include a metal, for example, tin (Sn), indium (In), bismuth (Bi), antimony (Sb), copper (Cu), silver (Ag), zinc (Zn), lead (Pb), or a combination thereof.

In the semiconductor package according to embodiments of the present disclosure, a vertical distance h4 from the upper surface 135u of the first contact pad 135 to the upper surface of the chip connector 137 may be greater than a sum of the vertical distance h1 from the upper surface 135u of the first contact pad 135 to the upper surface 131u of the first solder resist layer 131 and the vertical distance h2 from the upper surface 131u of the first solder resist layer 131 to the upper surface 132u of the second solder resist layer 132. For example, the chip connector 137 may protrude in the third direction Z beyond the second solder resist layer 132. For example, an upper surface of the chip connector 137 may be disposed at a higher level than the upper surface 132u of the second solder resist layer 132.

In the semiconductor package according to embodiments of the present disclosure, a vertical distance h3 may be measured from the first surface 110a of the base substrate 110 to the upper surface 131u of the first solder resist layer. A sum of a vertical distance h2 and vertical distance h3, which is from the first surface 110a of the base substrate 110 to the upper surface 132u of the second solder resist layer 132 may be greater than a half of the vertical distance h4 from the upper surface 135u of the first contact pad 135 to the upper surface of the chip connector 137. For example, a sum of thicknesses of the first solder resist layer 131 and the second solder resist layer 132 measured along the third direction Z may be greater than a half of a thickness of the chip connector 137 measured along the third direction Z. When the second solder resist layer 132 is sufficiently thicker than the first solder resist layer 131, a short circuit between adjacent chip connectors 137 may be prevented. Accordingly, a semiconductor package having increased performance may be provided.

In embodiments of the present disclosure illustrated in FIGS. 3 and 5, a maximum width w3 of the chip connector 137, measured along the first direction X may be equal to the width w2 of the second opening area OP2, measured along the first direction X. This may be a case in which the chip connector 137 contacts the side surface 132s of the second solder resist layer 132. Unlike the illustrated case, when the chip connector 137 does not contact the side surface 132s of the second solder resist layer 132, the maximum width w3 may be smaller than the width w2 of the second opening area OP2.

In embodiments of the present disclosure, when the width w2 of the second opening area OP2 is greater than or equal to the maximum width w3 of the chip connector 137, a short circuit between adjacent chip connectors 137 may be prevented due to the second solder resist layer 132. Accordingly, a semiconductor package having increased performance may be provided.

In embodiments of the present disclosure illustrated in FIGS. 4 and 6, the maximum width w3 of the chip connector 137 may be smaller than the width w2 of the second opening area OP2. This may be in both the case where the chip connector 137 contacts the side surface 132s of the second solder resist layer 132 and the case where the chip connector 137 does not contact the side surface 132s of the second solder resist layer 132.

The semiconductor chip 200 may be disposed on the chip substrate 100. The semiconductor chip 200 may be disposed on the chip connector 137. The semiconductor chip 200 may be in contact with the chip connector 137. The semiconductor chip 200 may be electrically connected to the first contact pad 135 of the chip substrate 100 through the chip connector 137.

The semiconductor chip 200 may be an Integrated Circuit (IC) in which hundreds to millions of semiconductor devices are integrated into one chip. For example, the semiconductor chip 200 may be an Application Processor (AP) such as a central processing unit (CPU), a graphic processing unit (GPU), a field-programmable gate array (FPGA), a digital signal processor, an encryption processor, a microprocessor, a microcontroller, or the like. However, embodiments of the present disclosure are not necessarily limited thereto. In addition, for example, the semiconductor chip 200 may be a logic chip such as an analog-digital converter (ADC) or an application specific IC (ASIC), or a memory chip such as a volatile memory (e.g., DRAM) or a non-volatile memory (e.g., ROM or flash memory). In addition, the semiconductor chip 200 may be embodied as a combination thereof.

The semiconductor chip 200 may include a chip passivation layer 210, a chip contact pad 215, and a chip mold layer 220.

The chip passivation film 210 may be disposed under the semiconductor chip 200. The chip passivation film 210 may be disposed on a bottom surface of the chip mold layer 220. The chip passivation film 210 may be in contact and cover the bottom surface of the chip mold layer 220. The bottom surface of the chip passivation film 210 may be disposed adjacent to the first surface 110a of the base substrate 110. The chip passivation film 210 may include an insulating material, for example, photo-imageable dielectric (PID).

The chip contact pad 215 may be disposed in the chip passivation film 210. The chip contact pad 215 may be surrounded with the chip passivation film 210. For example, the chip passivation layer 210 may cover side surfaces of the chip contact pad 215. The chip contact pad 215 may be disposed at the same level as that of the chip passivation layer 210. For example, upper and bottom surfaces of the chip contact pad 215 may be disposed at the same vertical levels as those of upper and bottom surfaces of the chip passivation film 210, respectively. The chip contact pad 215 might not be covered with the chip passivation film 210 so as to be exposed along the third direction Z. For example, a top surface and a bottom surface of the chip contact pad 215 might not be covered with the chip passivation film 210. The chip contact pad 215 may be in contact with the chip connector 137. The chip contact pad 215 may be electrically connected to the chip connector 137. The chip contact pad 215 may be electrically connected to the first contact pad 135, the conductive pattern 115, the package connector 57, and the circuit substrate 50 through the chip connector 137.

The chip mold layer 220 may be disposed on the chip passivation film 210. The chip mold layer 220 may surround transistors and multi-layered wirings in the semiconductor chip 200. The transistors may be electrically connected to the chip contact pad 215 through the multi-layered wirings and thus may be electrically connected to the chip substrate 100 and the circuit substrate 50.

A mold film 140 may cover the second solder resist layer 132 and the semiconductor chip 200. The mold film 140 may include, for example, an insulating polymer material such as an epoxy-based molding compound (EMC). However, embodiments of the present disclosure are not necessarily limited thereto.

An underfill film 145 may fill a space between the chip connectors 137. The underfill film 145 may surround and protect the chip connectors 137. The underfill film 145 may fill a space between the semiconductor chip 200 and the chip substrate 100. The underfill film 145 may be disposed between the semiconductor chip 200 and the second solder resist layer 132. For example, the underfill film 145 may be in contact with the chip connectors 137, upper surface 132u of the second solder resist layer, and the chip passivation layer 210. The underfill film 145 may fix the semiconductor chip 200 onto the chip substrate 100 and may prevent the semiconductor chip 200 from being broken or damaged.

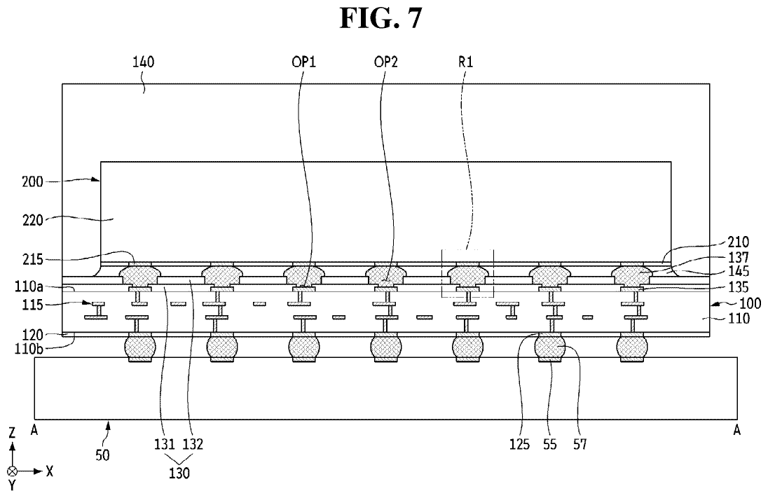

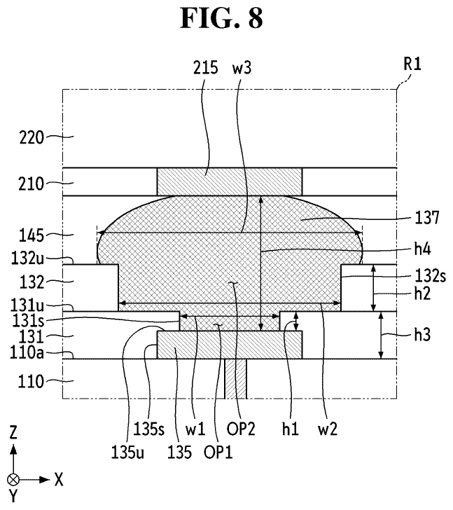

FIGS. 7 and 8 are diagrams for illustrating a semiconductor package according to embodiments of the present disclosure. To the extent that an element has not been described in detail, it may be assumed that the element is at least similar to corresponding elements that have been described in FIGS. 1 to 6.

Referring to FIGS. 7 and 8, the chip connector 137 may be disposed on the upper surface 132u of the second solder resist layer 132.

According to embodiments of the present disclosure, the chip connector 137 may overflow during the manufacturing process of the semiconductor package and thus may contact the upper surface 132u of the second solder resist layer 132.

In FIG. 8, the maximum width w3 of the chip connection member 137, measured along the first direction X may be greater than the width w2 of the second opening area OP2, measured along the first direction X. Unlike the illustrated example, a void or an air gap may be disposed between the chip connector 137 and the side surface 132s of the second solder resist layer 132.

In addition, although the chip connector 137 is illustrated as being in contact with both opposing upper surfaces 132u of the second solder resist layer 132 in the cross-sectional view of FIG. 8, the chip connector 137 may be in contact with only one of opposing upper surfaces 132u of the second solder resist layer 132. In this case, the maximum width w3 of the chip connector 137 may be greater or smaller than the width w2 of the second opening area OP2.

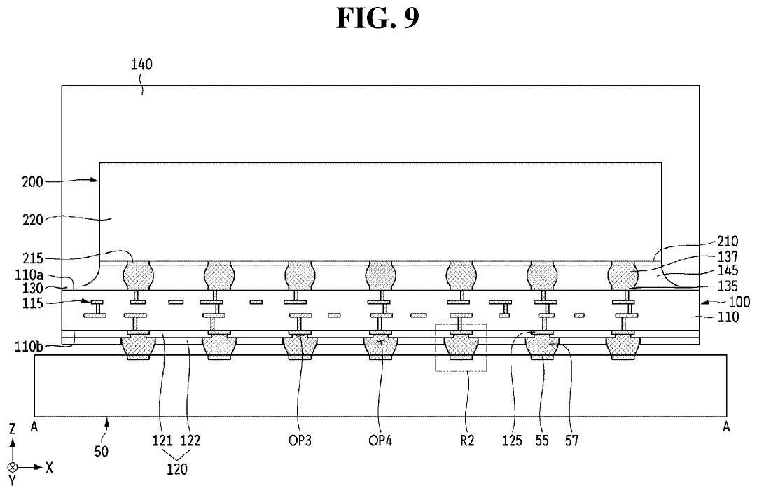

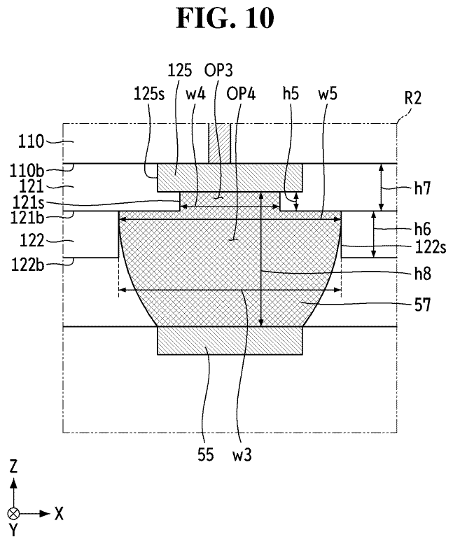

FIGS. 9 and 10 are diagrams for illustrating a semiconductor package according to embodiments of the present disclosure. To the extent that an element has not been described in detail, it may be assumed that the element is at least similar to corresponding elements that have been described in FIGS. 1 to 6.

Referring to FIGS. 9 and 10, the lower passivation film 120 may include a third solder resist layer 121 and a fourth solder resist layer 122.

According to embodiments of the present disclosure, unlike the embodiments as described with reference to FIGS. 1 to 6, the upper passivation film 130 may be embodied as a single film and may be disposed at the same level as that of the first contact pad 135. For example, the upper passivation film 130 may surround side surface 135s of the first contact pad 135.

According to embodiments of the present disclosure, the third solder resist layer 121 of the lower passivation film 120 may be disposed on the second surface 110b of the base substrate 110. The fourth solder resist layer 122 may be disposed on the third solder resist layer 121.

A portion of the third solder resist layer 121 may be disposed on the second contact pad 125. The third solder resist layer 121 may cover the side surface 125s and a portion of the bottom surface of the second contact pad 125 and the second surface 110b of the base substrate 110. In this regard, the bottom surface of the second contact pad 125 may refer to a surface that is disposed adjacent to the circuit substrate 50 among surfaces of the second contact pad 125 intersecting the third direction Z.

For example, in a plan view, the third solder resist layer 121 might not cover a portion of the bottom surface of the second contact pad 125 so as to be exposed along the third direction Z.

The third solder resist layer 121 may define a third opening area OP3 above the bottom surface of the second contact pad 125. The third opening area OP3 may refer to an area defined by the side surface 121s of the third solder resist layer 121 and the bottom surface of the second contact pad 125. In this regard, the side surface 121s of the third solder resist layer 121 may refer to a surface of the third solder resist layer 121 contacting the package connector 57 along the first direction X and a surface of the third solder resist layer 121 contacting the side surface 125s of the second contact pad 125.

A width w4 of the third opening area OP3 measured along the first direction X may be smaller than a width of the second contact pad 125, measured along the first direction X. The width of the third opening area OP3 may mean a distance between both opposing side surface 121s of the third solder resist layer 121, which are in contact with the package connector 57 along the first direction X. The width of the second contact pad 125 measured along the first direction X may mean a distance between both opposing side surfaces 125s of the first contact pad 125.

The fourth solder resist layer 122 may be disposed on the third solder resist layer 121. For example, the third solder resist layer 121 may be disposed between the fourth solder resist layer 122 and the base substrate 110. The fourth solder resist layer 122 may cover a portion of the bottom surface 121b of the third solder resist layer 121. The fourth solder resist layer 122 may overlap the third solder resist layer 121 along the third direction Z. As illustrated, the entirety of the fourth solder resist layer 122 may overlap the third solder resist layer 121 along the third direction Z. However, embodiments of the present disclosure are not necessarily limited thereto.

For example, in a plan view, the fourth solder resist layer 122 might not cover a portion of the bottom surface of the second contact pad 125 and a portion of the bottom surface 121b of the third solder resist layer 121 so as to be exposed along the third direction Z.

In embodiments of the present disclosure, a vertical distance h5 from the bottom surface of the second contact pad 125 to the bottom surface 121b of the third solder resist layer 121 may be smaller than a vertical distance h6 from the bottom surface 121b of the third solder resist layer 121 to the bottom surface 122b of the fourth solder resist layer 122. The vertical distance h6 from the bottom surface 121b of the third solder resist layer 121 to the bottom surface 122b of the fourth solder resist layer 122 may be at least two times longer than the vertical distance h5 from the bottom surface of the second contact pad 125 to the bottom surface 121b of the third solder resist layer 121. For example, the vertical distance h6 from the bottom surface 121b of the third solder resist layer 121 to the bottom surface 122b of the fourth solder resist layer 122 may be about 15 μm, and the vertical distance h5 from the bottom surface of the second contact pad 125 to the bottom surface 121b of the third solder resist layer 121 may be about 5 μm.

In the semiconductor package provided in embodiments of the present disclosure, the third solder resist layer 121 and the fourth solder resist layer 122 having a step shape may be sequentially stacked on the second contact pad 125 of the chip substrate 100, and a thickness (e.g., h5 of FIG. 10) of the third solder resist layer 121 may be reduced so that the package connector 57 is appropriately attached to the second contact pad 125, thereby preventing the performance of the semiconductor package from being deteriorated.

In addition, as the thickness of the third solder resist layer 121 is reduced, the width of the second contact pad 125 to be secured in order to allow the package connector 57 to be properly attached to the second contact pad 125 may be reduced. Accordingly, a semiconductor package having a reduced size and increased performance may be provided.

In addition, in the semiconductor package provided in embodiments of the present disclosure, the vertical distance h6 from the bottom surface 121b of the third solder resist layer 121 to the bottom surface 122b of the fourth solder resist layer 122 may be greater by at least twice than the vertical distance h5 from the bottom surface of the second contact pad 125 to the bottom surface 121b of the third solder resist layer 121. Accordingly, the side surface 122s of the fourth solder resist layer 122 may prevent a short circuit between the package connectors 57, thereby providing a semiconductor package with increased performance.

The fourth solder resist layer 122 may define a fourth opening area OP4 above the bottom surface 121b of the third solder resist layer 121 and the bottom surface of the second contact pad 125. The fourth opening area OP4 may refer to an area defined by the side surface 122s of the fourth solder resist layer 122, the bottom surface 121b of the third solder resist layer 121, and the bottom surface of the second contact pad 125. For example, the fourth opening area OP4 may overlap the third opening area OP3 along the third direction Z. For example, the fourth opening area OP4 may be disposed on the third opening area OP3. The fourth opening area OP4 may be in contact with the third opening area OP 3.

A width w5 of the fourth opening area OP4 may be greater than the width of the second contact pad 125. A width w5 in the first direction X of the fourth opening area OP4 may be greater than the width w4 of the third opening area OP3. For example, the width of the second contact pad 125 may be greater than the width w4 of the third opening area OP3, and the width w5 of the fourth opening area OP4 may be greater than the width of the second contact pad 125. The width w5 of the fourth opening area OP4 may mean a distance between both opposing side surfaces 122s measured along the first direction X of the fourth solder resist layer 122.

In the semiconductor package according to embodiments of the present disclosure, the width w5 of the fourth opening area OP4 may be greater than the width w4 of the third opening area OP3, so that the package connector 57 may be disposed on the bottom surface 121b of the third solder resist layer 121. For example, the package connector 57 may be disposed in the third opening area OP 3 and the fourth opening area OP 4, thereby preventing a short circuit from occurring between adjacent package connectors 57. Accordingly, a semiconductor package having increased performance may be provided.

In the semiconductor package according to embodiments of the present disclosure, a vertical distance h8 from the bottom surface of the second contact pad 125 to the upper surface of the package connector 57 may be greater than a sum of the vertical distance h5 from the bottom surface of the second contact pad 125 to the bottom surface 121b of the third solder resist layer 121 and the vertical distance h6 from the bottom surface 121b of the third solder resist layer 121 to the bottom surface 122b of the fourth solder resist layer 122. For example, the package connector 57 may protrude in the third direction Z beyond the fourth solder resist layer 122.

In the semiconductor package according to embodiments of the present disclosure, a vertical distance h6+h7 from the second surface 110b of the base substrate 110 to the bottom surface 122b of the fourth solder resist layer 122 may be greater than a half of the vertical distance h8 from the bottom surface of the second contact pad 125 to the upper surface of the package connector 57. For example, a sum of thicknesses of the third solder resist layer 121 and the fourth solder resist layer 122 along the third direction Z may be greater than a half of a thickness of the package connector 57 in the third direction Z. When the fourth solder resist layer 122 is sufficiently thicker than the third solder resist layer 121, a short circuit between adjacent package connectors 57 may be prevented. Accordingly, a semiconductor package having increased performance may be provided.

In embodiments of the present disclosure illustrated in FIG. 10, the maximum width w6 of the package connector 57 may be equal to the width w5 of the fourth opening area OP4. This may be a case in which the package connector 57 contacts the side surface 122s of the fourth solder resist layer 122. Unlike the illustrated case, when the package connector 57 does not contact the side surface 122s of the fourth solder resist layer 122, the maximum width w6 in the first direction X of the package connector 57 may be smaller than the width w5 in the first direction X of the fourth opening area OP4.

In embodiments of the present disclosure, when the width w5 of the fourth opening area OP4 is greater than or equal to the maximum width w6 of the package connector 57, a short circuit between adjacent package connectors 57 may be prevented due to the fourth solder resist layer 122. Accordingly, a semiconductor package having increased performance may be provided.

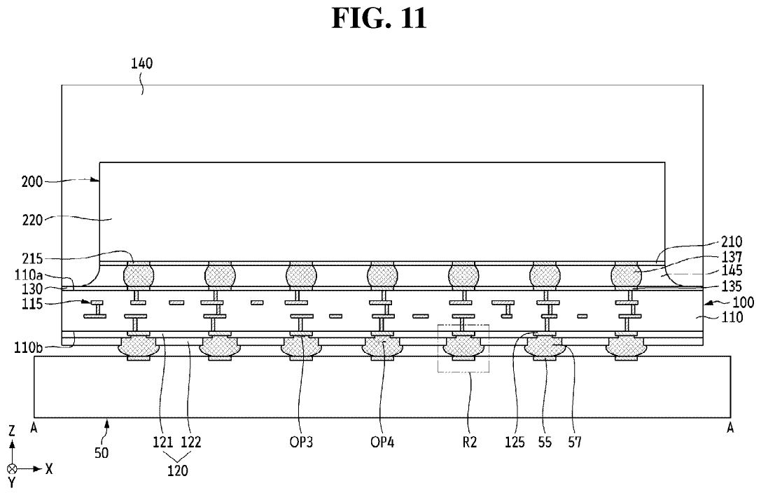

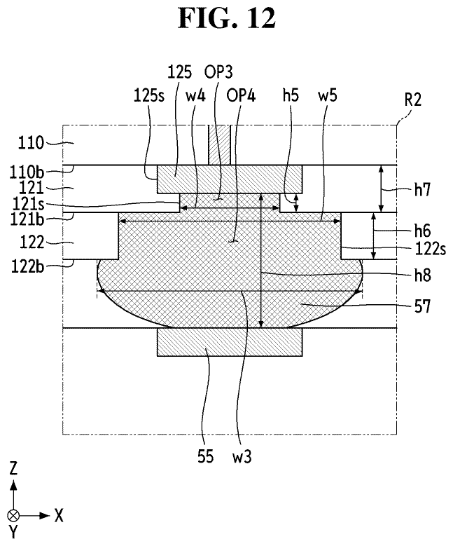

FIGS. 11 and 12 are diagrams for illustrating a semiconductor package according to embodiments of the present disclosure. To the extent that an element has not been described in detail, it may be assumed that the element is at least similar to corresponding elements that have been described in FIGS. 1 to 10.

Referring to FIGS. 11 and 12, the package connector 57 may be disposed on the bottom surface 122b of the fourth solder resist layer 122.

According to embodiments of the present disclosure, the package connector 57 may be overflow during the process for manufacturing the semiconductor package and thus may contact the bottom surface 122b of the fourth solder resist layer 122.

In FIG. 12, the maximum width w6 of the package connector 57 may be greater than the width w5 of the fourth opening area OP4.

In addition, although the package connector 57 is illustrated to be in contact with both opposing bottom surfaces 122b of the fourth solder resist layer 122 in the cross-sectional view of FIG. 12, the package connector 57 may be in contact with only one of the opposing bottom surfaces 122b of the fourth solder resist layer 122. In this case, the maximum width w6 in the first direction X of the package connector 57 may be greater or smaller than the width w5 of the fourth opening area OP4.

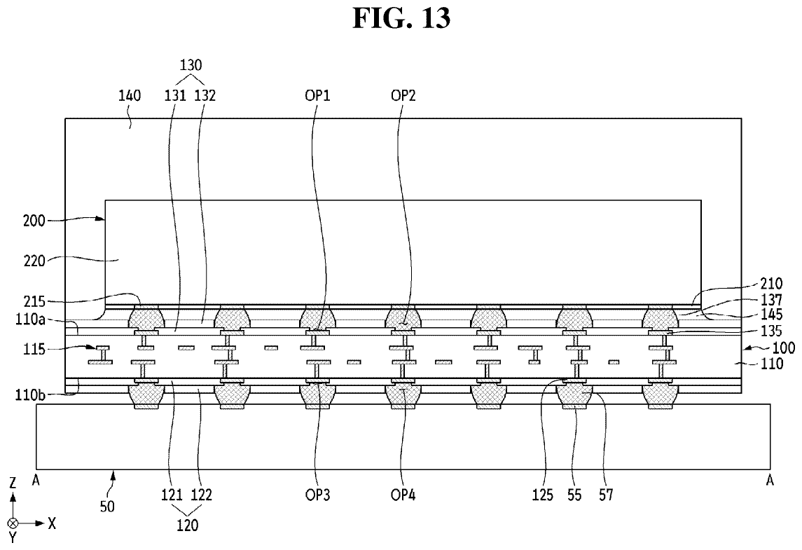

FIG. 13 is a schematic cross-sectional view for illustrating a semiconductor package according to embodiments of the present disclosure. To the extent that an element has not been described in detail, it may be assumed that the element is at least similar to corresponding elements that have been described in FIGS. 1 to 12.

Referring to FIG. 13, the upper passivation film 130 may include the first solder resist layer 131 and the second solder resist layer 132, and the lower passivation film 120 may include the third solder resist layer 121 and the fourth solder resist layer 122.

According to embodiments of the present disclosure, a semiconductor package including all of the first solder resist layer 131, the second solder resist layer 132, the third solder resist layer 121, and the fourth solder resist layer 122 may be provided. Accordingly, a semiconductor package having a reduced size and improved performance may be provided.

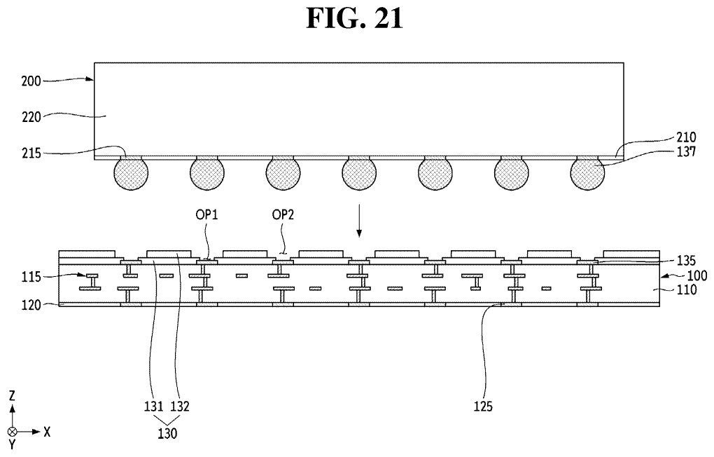

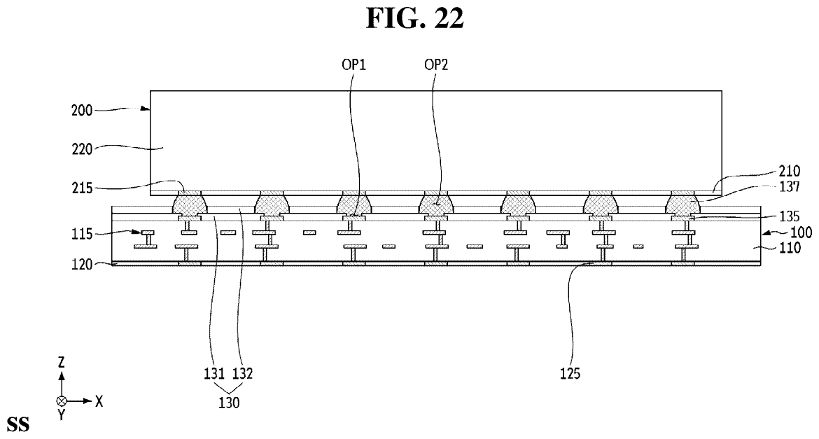

Hereinafter, a method for manufacturing a semiconductor package according to embodiments of the present disclosure will be described with reference to FIGS. 1 to 22.

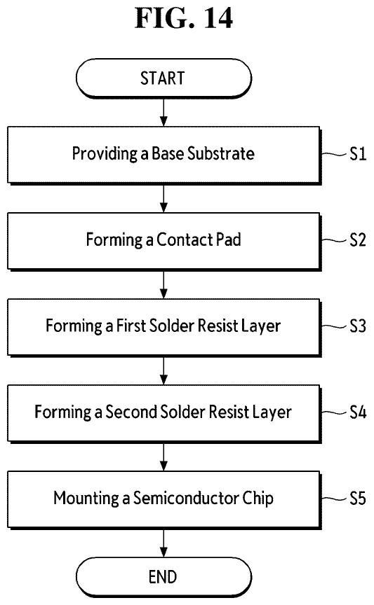

FIGS. 14 to 22 are diagrams illustrating intermediate structures corresponding to intermediate steps of a method for manufacturing a semiconductor package according to embodiments of the present disclosure.

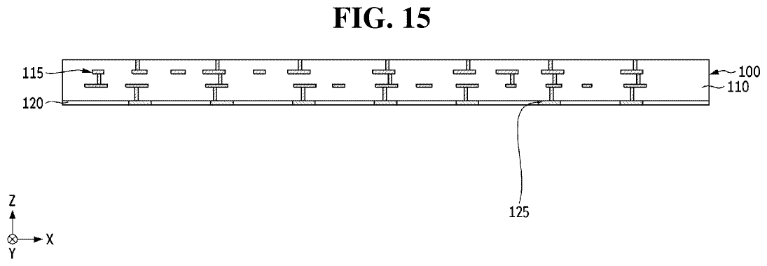

Referring to FIGS. 14 and 15, the base substrate 110 is provided in S1.

For example, the base substrate 110 may include the first surface 110a and the second surface 110b. The first surface 110a and the second surface 110b of the base substrate 110 may intersect the third direction Z in the perpendicular manner. The base substrate 110 is illustrated as a single layer. However, embodiments of the present disclosure are not necessarily limited thereto. The base substrate 110 may be comprised of, for example, a plurality of layers. The base substrate 110 may include an insulating material. The conductive pattern 115 may be disposed in the base substrate 110.

Subsequently, the lower passivation film 120 and the second contact pad 125 are disposed on the second surface 110b of the base substrate 110 in S2. The second contact pad 125 may be disposed in the lower passivation film 120. The second contact pad 125 may be electrically connected to the conductive pattern 115. The second contact pad 125 may include a conductive material, for example, a metal.

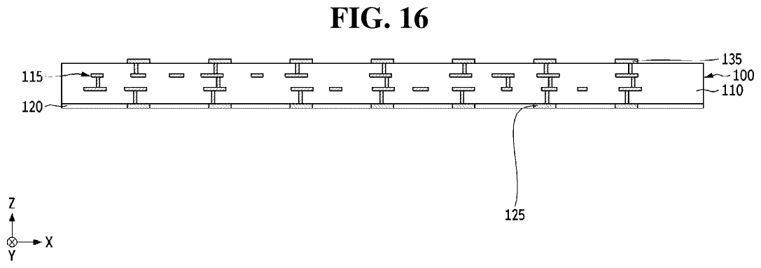

Next, referring to FIGS. 14 and 16, the first contact pad 135 is formed on the first surface 110a of the base substrate 110 in S2.

The first contact pad 135 may be formed to be electrically connected to the conductive pattern 115. The plurality of first contact pads 135 may be arranged side by side along the first direction X and the second direction Y in a matrix form. The first contact pad 135 may include a conductive material, for example, a metal.

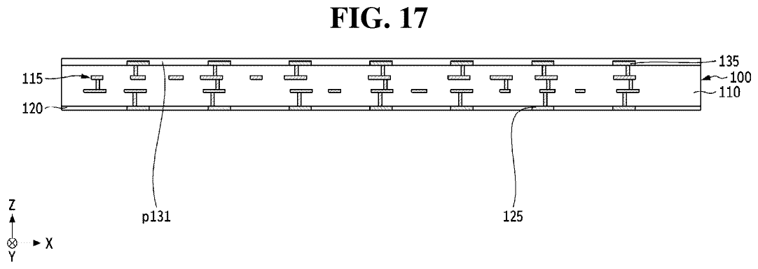

Subsequently, referring to FIG. 17, a preliminary first solder resist layer p131 may be formed.

The preliminary first solder resist layer p131 may be formed on the first surface 110a of the base substrate 110. The preliminary first solder resist layer p131 may be disposed to cover the first surface 110a of the base substrate 110 and the upper and side surfaces of the first contact pad 135.

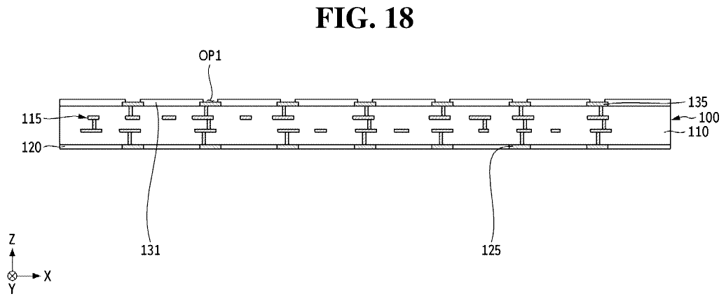

Next, referring to FIGS. 14 and 18, the first solder resist layer 131 is formed in S3.

For example, a portion of the preliminary first solder resist layer p131 may be removed and may expose the upper surface of the first contact pad 135 along the third direction Z. To the extent that an element has not been described in detail, it may be assumed that the element is at least similar to corresponding elements that have been described in FIGS. 1 to 13.

In addition, for example, the first opening area OP1 may be defined by the side surface of the first solder resist layer 131 and the upper surface of the first contact pad 135.

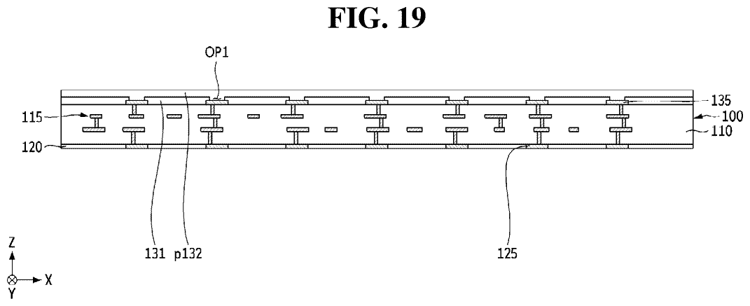

Next, referring to FIG. 19, a preliminary second solder resist layer 132 may be formed. The preliminary second solder resist layer 132 may be disposed on the first solder resist layer 132 and the first contact pad 135.

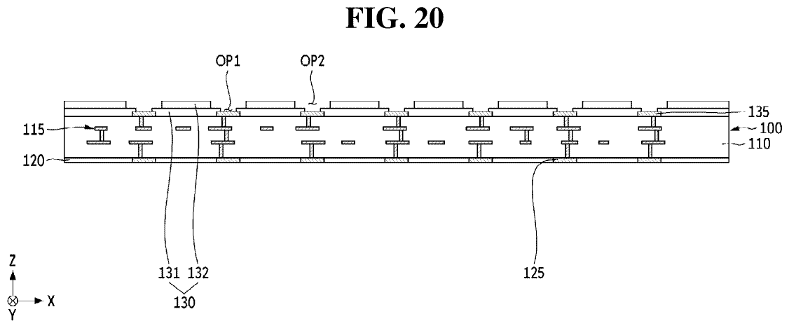

Next, referring to FIGS. 14 and 20, the second solder resist layer 132 is formed in S4.

For example, a portion of the preliminary second solder resist layer p132 may be removed and may expose the upper surface of the first contact pad 135 and the upper surface of the first solder resist layer 131 along the third direction Z. To the extent that an element has not been described in detail, it may be assumed that the element is at least similar to corresponding elements that have been described in FIGS. 1 to 13.

Next, referring to FIGS. 14, 21, and 22, the semiconductor chip 200 is mounted in S5.

For example, the chip connector 137 may approach the chip substrate 100 in a direction facing the first surface 110a of the base substrate 110. The semiconductor chip 200 may be aligned so that the chip connector 137 is aligned with the corresponding first contact pad 135. When the chip connector 137 has been disposed adjacent to the first opening area OP1 and the second opening area OP2, the chip connector 137 may be in contact with and electrically connected to the first contact pad 135 through a reflow process or the like.

In embodiments of the present disclosure, the first solder resist layer 131 and the second solder resist layer 132 may be sequentially stacked and may form the first solder resist layer 131 and the second solder resist layer 132 of the semiconductor package according to embodiments of the present disclosure as described with reference to FIGS. 1 to 6. Accordingly, the method for manufacturing the semiconductor package having the reduced size and increased performance may be provided.

Subsequently, the underfill film (scc 145 of FIG. 2) surrounding the semiconductor chip 200 and the first contact pad 135 may be formed.

Subsequently, the mold film (see 140 of FIG. 2) covering the semiconductor chip 200 and the second solder resist layer 132 may be formed.

Next, when the chip substrate 100 has been mounted on the circuit substrate (see 50 of FIG. 2), the semiconductor package according to embodiments of the present disclosure as described with reference to FIGS. 1 to 6 may be manufactured.

Although embodiments of the present disclosure have been described with reference to the accompanying drawings, the present disclosure is not necessarily limited to the above embodiments, but may be implemented in various different forms. A person skilled in the art may appreciate that the present disclosure may be practiced in other concrete forms without changing the technical spirit or essential characteristics of the present disclosure.

What is claimed is:

1. A semiconductor package, comprising:
a base substrate including a first surface and a second surface, opposite to each other along a first direction;
a first contact pad disposed on the first surface of the base substrate;
a first solder resist layer disposed on the first surface of the base substrate, covering a side surface and a portion of an upper surface of the first contact pad, and defining a first opening area on the first contact pad;
a second solder resist layer covering a portion of an upper surface of the first solder resist layer, and defining a second opening area on the first contact pad and the first solder resist layer; and
a first connector disposed in the first opening area and the second opening area, and in contact with the first contact pad,
wherein a second direction is parallel to the first surface, and a first width of the first opening area measured along the second direction is smaller than a second width of the second opening area measured along the second direction.

2. The semiconductor package of claim 1, further comprising:
a semiconductor chip disposed on and in contact with the first connector and electrically connected to the first contact pad; and
an underfill film disposed between the semiconductor chip and the second solder resist layer and surrounding the first connector.

3. The semiconductor package of claim 1, wherein a vertical distance from an upper surface of the first contact pad to an upper surface of the first solder resist layer is smaller than a vertical distance from an upper surface of the first solder resist layer to an upper surface of the second solder resist layer.

4. The semiconductor package of claim 1, wherein a vertical distance from an upper surface of the first solder resist layer to an upper surface of the second solder resist layer is at least twice than a vertical distance from an upper surface of the first contact pad to an upper surface of the first solder resist layer.

5. The semiconductor package of claim 4, wherein the vertical distance from the upper surface of the first contact pad to the upper surface of the first solder resist layer is about 5 μm or greater.

6. The semiconductor package of claim 1, wherein a third width of the first connector is greater than the first width of the first opening area.

7. The semiconductor package of claim 6, wherein the third width in of the first connector is greater than the second width of the second opening area.

8. The semiconductor package of claim 6, wherein the third width of the first connector is smaller than the second width of the second opening area.

9. The semiconductor package of claim 1, wherein a first angle defined between a side surface of the first solder resist layer and an upper surface of the first contact pad is different from a second angle defined between a side surface of the second solder resist layer and an upper surface of the first solder resist layer.

10. The semiconductor package of claim 9, wherein the first angle is greater than the second angle.

11. The semiconductor package of claim 1, further comprising:
a second contact pad disposed on the second surface;
a third solder resist layer disposed on the second surface and covering a side surface and a portion of a bottom surface of the second contact pad, and defining a third opening area on the second contact pad; and
a fourth solder resist layer covering a portion of a bottom surface of the third solder resist layer, and defining a fourth opening area on the second contact pad and the third solder resist layer.

12. The semiconductor package of claim 11, further comprising:
a second connector disposed in the third opening area and the fourth opening area, and in contact with the second contact pad; and
a circuit substrate disposed on and in contact with the second connector and electrically connected to the second contact pad,
wherein a third width of the third opening area is smaller than a fourth width of the fourth opening area.

13. The semiconductor package of claim 11, wherein a vertical distance from a bottom surface of the second contact pad to a bottom surface of the third solder resist layer is smaller than a vertical distance from a bottom surface of the third solder resist layer to a bottom surface of the fourth solder resist layer.

14. A semiconductor package, comprising:
a base substrate including a first surface and a second surface, opposite to each other along a first direction;
a first contact pad disposed on the first surface;
a first solder resist layer disposed on the first surface and covering a side surface and a portion of an upper surface of the first contact pad, and defining a first opening area on the first contact pad;
a second solder resist layer covering a portion of an upper surface of the first solder resist layer, and defining a second opening area on the first contact pad and the first solder resist layer;
a first connector disposed in the first opening area and the second opening area, and in contact with the first contact pad;
a semiconductor chip disposed on and in contact with the first connector and electrically connected to the first contact pad; and
an underfill film disposed between the semiconductor chip and the second solder resist layer and surrounding the first connector,
wherein a second direction is parallel to the first surface, and a first width of the first opening area measured along the second direction is smaller than a second width of the second opening area measured along the second direction,
wherein the first connector protrudes in the first direction beyond the second solder resist layer.

15. The semiconductor package of claim 14, wherein a vertical distance from an upper surface of the first contact pad to an upper surface of the first solder resist layer is smaller than a vertical distance from an upper surface of the first solder resist layer to an upper surface of the second solder resist layer.

16. The semiconductor package of claim 14, wherein a portion of the first connector is disposed on a bottom surface of the first solder resist layer.

17. The semiconductor package of claim 14, further comprising:
a second contact pad disposed on the second surface,
a third solder resist layer disposed on the second surface and covering a side surface and a portion of a bottom surface of the second contact pad, and defining a third opening area on the second contact pad; and
a fourth solder resist layer covering a portion of a bottom surface of the third solder resist layer, and defining a fourth opening area on the second contact pad and the third solder resist layer.

18. The semiconductor package of claim 17, further comprising:
a second connector disposed in the third opening area and the fourth opening area, and in contact with the second contact pad; and
a circuit substrate disposed on the second connector, in contact with the second connector and connected to the second contact pad,
wherein a third width of the third opening area is smaller than a fourth width of the fourth opening area.

19. A method for manufacturing a semiconductor package, the method comprising:
providing a base substrate including a first surface and a second surface, opposite to each other along a first direction;
disposing a contact pad on the first surface;
disposing a first solder resist layer on the first surface and covering a side surface and a portion of an upper surface of the contact pad;
disposing a second solder resist layer covering a portion of an upper surface of the first solder resist layer; and
mounting a semiconductor chip on the first surface, such that it is electrically connected to the contact pad,
wherein the first solder resist layer defines a first opening area on the contact pad,
wherein the second solder resist layer defines a second opening area on the contact pad and the first solder resist layer,
wherein the semiconductor chip includes a chip connector disposed in the first opening area and the second opening area, and in contact with the contact pad,
wherein a second direction is parallel to the first surface, and a first width of the first opening area measured along the second direction is smaller than a second width of the second opening area measured along the second direction.

20. The method of claim 19, wherein a vertical distance from an upper surface of the contact pad to an upper surface of the first solder resist layer is smaller than a vertical distance from an upper surface of the first solder resist layer to an upper surface of the second solder resist layer.
